(19) United States
(12) Patent Application Publication
(10) Pub. No.: US 2008/0284041 A1
(43) Pub. Date: Nov. 20, 2008

(54) SEMICONDUCTOR PACKAGE WITH THROUGH SILICON VIA AND RELATED METHOD OF FABRICATION

(75) Inventors: Hyung-sun JANG, Suwon-si (KR); Un-byoung KANG, Hwasung-si (KR); Woon-seong KWON, Suwon-si (KR); Young-chai KWON, Suwon-si (KR); Chung-sun LEE, Gunpo-si (KR); Dong-ho LEE, Sungnam-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/045,840

(22) Filed: Mar. 11, 2008

(30) Foreign Application Priority Data
May 18, 2007 (KR) 10-2007-0048911
Nov. 30, 2007 (KR) 10-2007-0123811

(51) Int. Cl. H01L 23/48

(52) U.S. Cl. 257/774; 257/E23.01

(57) ABSTRACT

In a semiconductor package, an electrode has a first part extending through a semiconductor substrate and a second part extending from the first part through a compositional layer to reach a conductive pad.

### CROSS-REFERENCE TO RELATED APPLICATIONS

This application claims priority to Korean Patent Applications. 10-2007-0048911 filed on May 18, 2007 and 10-2007-0123811 fitted Nov. 30, 2007, the collective subject matter of which is hereby incorporated by reference.

### BACKGROUND OF THE INVENTION

1. Field of the Invention

The invention relates generally to semiconductor integrated circuit (IC) packages. More particularly, the invention relates to semiconductor IC packages including a through silicon via and related electrode, as well as methods of fabricating same.

2. Description of Related Art

Modern electronic devices rely on integrated circuit (IC) technology to provide a wide variety of functionality, including, for example, data storage, data processing, signal amplification, signal transduction, and so on. Some common examples of IC technology providing this functionality include memory chips and microprocessors used in personal computers and portable electronic devices, light sensors used in cameras and motion detectors, and digital transceivers used in communication devices, to name but a few.

To incorporate IC technology into a particular electronic device or system, an IC pattern including various circuit components is typically formed on a semiconductor wafer. The wafer is then diced into several IC chips and the IC chips are subsequently connected to other components of the electronic device or system e.g., to a printed circuit board (PCB). In an effort to maximize an amount of functionality per area, some devices include multiple IC chips stacked on top of each other and jointly mounted on the PCB as a unit.

In general, any composite structure including one or more semiconductor IC chips and associated connection interfaces adapted to be jointly mounted on a PCB or some other interconnection platform can be referred to as a “semiconductor IC package,” or an “IC package”. Most conventional IC packages are mounted onto a PCB by connecting (e.g., by soldering) external terminals of the IC package to the PCB, either directly or via wire bonding. One common example of such an IC package is a ball grid array (BGA) package, which comprises a plurality of stacked IC chips connected to a PCB via wire bonding. Other types of IC packages may be mounted on a PCB or other interconnection platform using bonding techniques such as tape automated bonding (TAB) or flip-chip bonding.

Unfortunately, most of these conventional interconnection technologies for IC packages are either undesirably complicated or they tend to limit the degree to which the IC packages can be miniaturized. For instance, to form a conventional BGA package, a wafer including IC patterns for the BGA package must be diced before the wire bonding for the BGA can be formed. However, the formation of the wire bonding complicates the process of forming the BGA package and limits the degree to which the BGA package can be miniaturized.

More recently, wafer level processing (WLP) techniques have been developed to allow various features of IC packages to be formed within a wafer before the wafer is diced. For instance, certain WLP techniques are used to form device interconnection features together with other wafer processing steps, thereby avoiding the need to form wire bonding after IC chips are diced.

In general, such WLP techniques allow IC package manufacturing processes to be streamlined and consolidated. Moreover, WLP techniques can generally be performed in parallel on a plurality of IC chips arranged in a matrix on the wafer, thereby allowing a plurality of IC chips to be formed and tested while still in a wafer stage. By performing WLP techniques in parallel across a plurality of IC chips, IC package manufacturing throughput is increased and the total time and cost required to fabricate and test IC packages is decreased accordingly. In addition, by forming features such as device interconnections at the wafer level, the overall size of IC packages can be reduced.

One of the WLP techniques used to form device interconnections involves the formation of a through silicon via. A through silicon via (TSV) is usually formed by creating a hole through a semiconductor substrate and/or various material layers formed on the substrate, and then forming a penetration electrode in the hole. The penetration electrode may be connected to internal features of an IC chip such as signal terminals, data transmission lines, transistors, buffers, and so on. In addition, the penetration electrode may be connected to features external to the IC chip, such as a PCB, via an external terminal.

Various examples of TSVs incorporated in IC chips are disclosed, for example, in U.S. Pat. No. 6,873,054, U.S. Pat. No. 7,045,870, and published U.S. Patent Application No. 2007/0054419, the collective subject matter of which is hereby incorporated by reference.

### SUMMARY OF THE INVENTION

In order to provide IC packages with improved electrical interconnections, as compared with conventional IC packages, selected embodiments of the invention include IC packages and related methods of manufacture, wherein an electrode is formed to penetrate a semiconductor substrate, all or part of an overlaying compositional layer, and/or all or part of a contact pad.

In one embodiment, the invention provides a semiconductor integrated circuit (IC) package, comprising; a substrate having a first surface and a second surface, a compositional layer formed on the first surface, a conductive pad formed on, or formed at least partially in the compositional layer, an electrode comprising a first part extending through the substrate from the second surface, and a second part extending from the first part through the compositional layer to electrically contact the conductive pad, and a spacer insulation layer separating the first part of the electrode from the substrate.

In another embodiment, the invention provides a method of forming a semiconductor package, the method comprising; forming a compositional layer on a first surface of a substrate, forming a conductive pad on, or at least partially in the compositional layer, forming a first via hole through the substrate from a second surface of the substrate opposing the first surface of the substrate, forming a spacer insulation layer on inner surfaces of the first via hole, forming a second via hole through the spacer insulation layer to extend through the compositional layer to reach the conductive pad, forming an electrode comprising a first part disposed in the first via hole and a second part disposed in the second via hole, wherein the second part of the electrode makes electrical contact with the conductive pad.

In another embodiment, the invention provides a semiconductor integrated circuit (IC) optical device module, comprising; a substrate having opposing first and second surfaces, an active pixel sensor formed on the first surface, a compositional layer formed on the first surface and contacting at least a portion of the active pixel sensor, a conductive pad formed on, or formed at least partially in the compositional layer, an electrode comprising a first part extending through the substrate from the second surface, and a second part extending from the first part through the compositional layer to reach the conductive pad, a spacer insulation layer disposed between the first part of the electrode and the substrate, and a transparent substrate disposed on the substrate over the active pixel sensor.

In another embodiment, the invention provides an electronic system, comprising; a controller operatively connected to a semiconductor package via a bus, an input/output (IO) interface allowing data transfers between the semiconductor package and the controller via the bus, wherein the semiconductor package comprises; a substrate having opposing first and second surfaces, a semiconductor device disposed on the first surface of the substrate, a compositional layer formed on the first surface of the substrate and contacting at least a portion of the semiconductor device, a conductive pad formed on, or formed at least partially in the compositional layer, an electrode comprising a first part extending through the substrate from the second surface, and a second part extending from the first part through the compositional layer to reach the conductive pad, and a spacer insulation layer separating the first part of the electrode from the substrate.

### BRIEF DESCRIPTION OF THE DRAWINGS

Embodiments of the invention are described below in relation to the accompanying drawings. Throughout the drawings like reference numbers indicate like or similar features. In the drawings:

Figures (FIGS.) 1 through 10 are schematic diagrams variously illustrating a semiconductor package in accordance with selected embodiments of the invention;

FIGS. 11A through 11G are related schematic diagrams illustrating a method of forming a semiconductor package in accordance with an embodiment of the invention;

FIGS. 12A through 12E are related schematic diagrams illustrating a method of forming a semiconductor package in accordance with another embodiment of the invention;

FIGS. 13A through 13D are related schematic diagrams illustrating a method of forming a semiconductor package in accordance with another embodiment of the invention;

FIG. 14 is a schematic diagram illustrating a package module for a semiconductor device according to an embodiment of the invention; and

FIG. 15 is a general block diagram of a system including a semiconductor package in accordance with an embodiment of the invention.

### DESCRIPTION OF EMBODIMENTS

Embodiments of the invention are described below with reference to the corresponding drawings. These embodiments are presented as teaching examples while the actual scope of the invention is defined by the claims that follow.

FIGS. 1 through 10 are schematic diagrams variously illustrating a semiconductor package 100 in accordance with selected embodiments of the invention. Semiconductor package 100 may be used to implement a semiconductor device such as a dynamic random access memory (DRAM), a static random access memory (SRAM), a non-volatile memory such as a flash memory, or an active pixel sensor (e.g., a complementary metal-oxide semiconductor (CMOS) image sensor), etc.

Referring to FIG. 1, semiconductor package 100 comprises a semiconductor substrate 105 having a first (upper) surface 1051 and a second (lower) surface 1052. Semiconductor substrate 105 may be conventionally formed from a silicon (Si) wafer, a germanium (Ge) wafer, and/or a silicon-germanium (SiGe) wafer, etc.

In this regard, the terms upper/lower, as well as similar terms such as over/under, vertical/horizontal, etc., have relative geometric meaning in the description that follows. Such geometric meaning is typically drawn to an illustrated embodiment of the invention, but those of ordinary skill in the art will recognize that such terms are used merely to distinguish related elements and should not be construed as mandating a particular orientation or device geometry. In addition, terms such as “on” or “over” are used in the description that follows without reference to a particular orientation. For example, an outer layer may be described as being “on” or “over” an inner layer even if the outer layer is located below the inner layer when viewed from one particular orientation. Further, the term “on” may be used to describe a relationship between two layers or elements in which one is directly on the other, or intervening layers or elements may be present.

In some embodiments, an upper surface of semiconductor substrate 105 may also be designated as a “front face” and a lower surface of semiconductor substrate 105 may be designated a “back face” with reference to subsequently applied semiconductor fabrication processes. For example, a “back face” laser drilling process may be used to form holes in lower surface 1052 of semiconductor substrate 105, or “back face” grinding may be used to modify the thickness of semiconductor substrate 105 from its lower surface 1052, and so on.

A semiconductor device 110 such as a memory device or a logic device is disposed on semiconductor substrate 105. Semiconductor device 110 may take many different physical forms and may be alternately referred to as a “semiconductor chip.”

An insulating layer (i.e., a compositional layer 115) is formed on semiconductor substrate 105 and semiconductor 110 to protect and prevent undesired electrical contact with semiconductor device 110. At least in part, compositional layer 115 may be formed from one or more conventionally understood non-conductive materials. In one embodiment of the invention, compositional layer 115 takes the form of an intermediate dielectric layer of conventional composition.

While the illustrated embodiments assume that compositional layer 115 is formed from a single material on first surface 1051 of semiconductor substrate 105, those of ordinary skill in the art will recognize that more complex insulating and/or functional layers and/or elements may be alternately or additionally used. For example, compositional layer 115 may be formed from different insulating material disposed in one or more layers. Alternately, one or more functional or conductive material layers or elements may be incorporated (e.g., embedded) within compositional layer 115. For example, in certain embodiments of the invention where semiconductor device 110 is an active pixel sensor, an optical filter (e.g., an infrared (IR) filter) may be incorporated within compositional layer 115. However, in the simple example illustrated in FIG. 1, compositional layer 115 separates semiconductor device 110 from subsequently formed passivation layer 127.

A conductive pad 120 is formed on (or within) compositional layer 115. Conductive pad 120 may be conventionally formed from one or more materials such as a metal or metal alloy (e.g., copper or aluminum), a metal silicide, etc. In the illustrated embodiment of FIG. 1, conductive pad 120 is assumed to be electrically connected to semiconductor device 110 via a conventional signal path (e.g., wire(s), metal trace(s), additional intervening circuit(s), and/or conductive plug(s), etc.).

As shown in FIGS. 1 through 10, conductive pad 120 may be at least partially embedded within compositional layer 115, leaving an upper surface of conductive pad 120 exposed in (e.g., disposed flush with) the upper surface of compositional layer 115. In other embodiments of the invention, conductive pad 120 may be formed partly or entirely above the upper surface of compositional layer 115, or buried within compositional layer 115.

An electrode 155 is formed through silicon via, or “through hole”, penetrating semiconductor substrate 105 to reach conductive pad 120. In the illustrated embodiment of FIGS. 1 through 10, the through hole comprises a first via hole 140 penetrating at least semiconductor substrate 105, and a second via hole 150 penetrating at least a portion of compositional layer 115 and at least a portion of conductive pad 120. In the illustrated embodiment of FIG. 1, second via hole 150 has a smaller cross-sectional width (e.g., diameter) than first via hole 140. Further, second via hole 150 illustrated n FIGS. 1 through 6 extends completely through conductive pad 120 and extends above the upper surface of compositional layer 115. However, second via hole 150 may be alternatively formed to penetrate only a portion of conductive pad 120, or to penetrate to make contact with a lower surface of conductive pad 120 but not extend into conductive pad 120.

Electrode 155 may be formed from one or more conductive materials including (e.g.) a metal, a metal alloy, and/or a metal silicide, etc. Further, electrode 155 may include one or more barrier layers associated with a particular conductive material.

A spacer insulation layer 145 may be used, as needed, to separate or insulate electrode 155 from substrate 105 and related material layers.

Those of ordinary skill in the art will understand that the respective geometries of first and second via holes 140 and 150 are a matter of design choice, as is the geometry of electrode 155. Alternate embodiment examples are illustrated between FIGS. 1 through 10.

For example, in the embodiment illustrated in FIG. 2, first via hole 140 extends through at least a portion of compositional layer 115 and the geometry of electrode 155 and other features changes accordingly. Similarly, in the embodiment of FIG. 3, first and second via holes 140 and 150 are formed with a tapered shape (i.e., with a descending cross-section as a function of vertical extension) and the geometry of electrode 155 and other related features changes accordingly.

In the alternate embodiments of FIGS. 1 through 10, electrode 155 may be viewed as comprising a first part formed in first via hole 140 and a second part formed in second via hole 150. (Such first and second parts may be coincidentally formed during one or more fabrication processes, but may be conceptually viewed as different parts for clarity of description). Electrode 155 may further be associated with a re-routing layer 156 (e.g., a distribution line, or terminal connection) formed on lower surface 1052 of semiconductor substrate 105. As illustrated, the second part of electrode 155 may extend above the upper surface of compositional layer 115 and conductive pad 120 in certain embodiments of the invention, or the second part of electrode 155 may be formed to terminate flush with the upper surface of compositional layer 115, or within conductive pad 120, for example.

As required by the selection of various materials used to fabricate semiconductor package 100, spacer insulation layer 145 may be interposed between the first part of electrode 155 and semiconductor substrate 105, or between the first part of electrode 155 and semiconductor substrate 105 and compositional layer 115. In addition, spacer insulation layer 145 may also be formed on lower surface 1052 of semiconductor substrate 105, as shown in FIG. 1 to separate re-routing layer 156 from substrate 105. In many embodiments of the invention, spacer insulation layer 145 will be used to insulate portions of electrode 155 from semiconductor substrate 105 and other material layers to provide a more reliable connection between electrode 155 and conductive pad 120.

In certain embodiments of the invention, the first part of electrode 155 will be formed to completely fill residual portions of first via hole 140 containing spacer insulation layer 145. However, the first part of electrode 155 may alternately be formed to fill only part of the residual portion of first via hole 140 leaving one or more material voids. For example, the first part of electrode 155 may be formed, as suggested by FIG. 1, without a central portion indicated by the dotted box. In other words, in at least one alternative embodiment if the invention, the first part of electrode 155 is conformally formed in first via hole 140 to leave a centrally disposed void. Similarly, the second part of electrode 155 may be conformably formed within second via hole 150.

A separating insulation layer 160 is formed on lower surface 1052 of semiconductor substrate 105 over spacer insulation layer 145 (where present) and exposed portions (e.g., re-routing layer 156) of electrode 155, extending over lower surface 1052 of substrate 105. One or more openings will typically be formed in insulation layer 160 to allow electrical connection of electrode 155 with a terminal 165. In the illustrated embodiments of FIGS. 1 through 10, terminal 165 is shown as a solder bump or a solder ball. However, terminal 165 may have any reasonable geometry and may be fabricated using any one of a number of conventional techniques.

In the embodiments shown in FIGS. 1 through 10, an opening in insulation layer 160 allowing connection to terminal 165 may be laterally disposed along re-routing layer 156 of electrode 155. However, in other embodiments of the invention, the opening may be disposed such that terminal 165 is disposed directly under (i.e., in vertical alignment with) electrode 155. In such embodiments, re-routing layer 156 of electrode 155 may be omitted.

A noted above, passivation layer 127 may be formed on compositional layer 115 in certain embodiments of the invention. Passivation layer 127 may be used to protect certain under-layers or components of semiconductor package 100 from the effects of heat, humidity, potentially corrosive chemicals and dopant materials, as well as subsequently applied fabrication processes, etc. In one embodiment, passivation layer 127 is formed from a nitride layer, but other conventional materials may be used in view of the other materials used to fabricate semiconductor package 100. In another embodiment of the invention, passivation layer 127 is formed from a polyimide layer. In other embodiments of the invention, passivation layer 127 may be completely omitted. In the illustrated embodiments of the invention shown in FIGS. 1 through 10, at least a portion of conduction pad 120 and/or a portion of electrode 155 are exposed through an opening formed in passivation layer 127.

In the illustrated embodiments, a handling substrate 130 is attached to passivation layer 127 (or to an upper layer of the structure comprising electrode 155) to facilitate further processing of substrate 105. In general, handling substrate 130 provides protection to components and features of semiconductor package 100 and imparts structural stability during subsequent fabrication processing. The material used to form handling substrate 130 may be selected to have a similar thermal expansion coefficient relative to semiconductor substrate 105 in order to prevent warping and twisting of semiconductor package 100.

Handling substrate 130 may be adhered to or bonded with passivation layer 127 using one or more of a number of conventionally available adhesives 125. In the illustrated embodiments of FIGS. 1 through 10, adhesive 125 is formed over conductive pad 120 and any exposed portion of electrode 155. The use of an adhesive 125 as well as handling wafer 130 is, however, optional.

In certain embodiments of the invention where semiconductor device 110 comprises a light sensor such as an active pixel sensor, handling substrate 130 may be formed from a transparent material such as a glass in order to facilitate the transmission of incident light to semiconductor device 110. In addition, where semiconductor device 110 comprises a light sensor, the light sensor may be formed to extend between the upper surface of semiconductor substrate 105 and the upper surface of compositional layer 115 or passivation layer 127, such that incident light passing through transparent handling substrate 130 is able to reach the light sensor without attenuation by intervening material layers.

For example, FIG. 4 illustrates an embodiment of semiconductor package 100 where semiconductor device 110 comprises a CMOS image sensor (CIS). In the embodiment of FIG. 4, the CIS is formed on the upper surface of semiconductor substrate 105 and extends to the upper surface of passivation layer 127 (i.e., is not covered by compositional layer 115 or passivation layer 127). Within this configuration, the CIS is separated from handling substrate 130 by a sealed internal space 157. That is, in one embodiment of the invention, sealed internal space 157 is formed over semiconductor device 110 without intervening material layers by selective application of adhesive 125 outside of areas containing semiconductor device 110. As a result, incident light transmitted through handling substrate 130 may reach the CIS without significant attenuation.

FIG. 5 illustrates yet another embodiment of semiconductor package 100 comprising semiconductor device 110. Here again, semiconductor device 110 is assumed to be an image sensor, such as those conventionally available and comprising an active pixel sensor array. However, semiconductor device 110, instead of being formed on the upper surface of substrate 105, is formed on or in a recess disposed with the upper surface of substrate 105. Thus, an upper surface of semiconductor device 110 may be essentially flush with the upper surface of substrate 105.

Again, handling substrate 130 is assumed to be a transparent material (e.g., glass) capable of passing light in a defined optical bandwidth. Portions of compositional layer 115, passivation layer 127, and/or adhesive 125 may either be selectively removed from, or not formed over the area of substrate 105 containing semiconductor device 110. In this manner, sealed internal space 157 may be formed between handling substrate 130 and semiconductor device 110.

In addition to the foregoing modifications, the embodiment of the invention illustrated in FIG. 5 comprises a different arrangement between electrode 155 and conductive pad 120. Namely, a conductive bump structure 122 is formed over at least a portion of electrode 155 extending above conductive pad 120. In certain embodiments of the invention, bump 122 may also be formed on at least a portion of conductive pad 120. Bump 122 may thus be used to provide improved electrical contact between conductive pad 120 and electrode 155 as well as potentially forming an improved connection surface (e.g., a surface pre-wetted with a selected conductive material such as solder) for a later formed connection.

FIG. 6 illustrates yet another embodiment of semiconductor package 100 where semiconductor device 110 has a different size and disposition relative to the embodiments previously described in relation to FIGS. 1 through 5. In the embodiment of FIG. 6, semiconductor device 110 is formed on the upper surface semiconductor substrate 105. However, the semiconductor device 110 is sized to have approximately the same thickness as compositional layer 115. That is, the upper surface of semiconductor device 110 is essentially flush with the upper surface of compositional layer 115. This arrangement is well suited to non light-sensing applications and allows passivation layer 127 to be formed with relative uniformity over both compositional layer 115 and semiconductor device 110.

FIG. 7 illustrates yet another embodiment of semiconductor package 100 comprising semiconductor device 110. Here, in contrast to the embodiment illustrated in FIG. 6, semiconductor device 110 has a thickness substantially less than compositional layer 115 and is covered by a portion of compositional layer 115 and passivation layer 127. In addition, electrode 155 is shown in a non-penetrating relationship to conductive pad 120. That is, second via hole 150 extends only to expose a lower surface of conductive pad 120, and electrode 155 is formed in electrical contact with conductive pad 120, but not in a manner that substantially penetrates the material forming conductive pad 120. Within the arrangement illustrated in FIG. 7, first via hole 140 extends through the thickness of substrate 105, but does not continue into compositional layer 115. Second via hole 150 may be subsequently formed using conductive pad 120 as an etch stop. The embodiment of FIG. 7 may be particularly useful in applications where contamination of first via hole 140 by material residue caused by the penetration of conductive pad 120 is a concern (i.e., where the conductive properties of electrode 155 and/or spacer insulation layer 145 might be adversely effected by residue from conductive pad 120).

In contrast, the embodiment shown in FIG. 8 comprises a first via hole 140 that extends at least partially into compositional layer 115. Second via hole 150 extends from first via hole 140 and penetrates any residual portion of compositional layer 115 and conductive pad 120. As before, electrode 155 may be formed in conjunction with spacer insulation layer 145 separating a first part of electrode 155 from substrate 105 and/or compositional layer 115.

FIG. 9 illustrates yet another embodiment of semiconductor package 100 comprising semiconductor device 110. Unlike the former illustrated embodiments, however, at least the first part of electrode 155 comprises one or more barrier layer(s) as well as one or more conductive materials. That is, spacer insulation layer 145 is formed, as need, on the exposed inner surfaces of first via hole 140. Then, a barrier layer 152 is formed on spacer insulation layer 145 (or directly on the inner surfaces of first via hole 140). Then, one or more conductive material(s) 154 are used to fill (or partially fill) the residual portion of first via hole 140 as well as second via hole 150 to form electrode 155.

Thus, barrier layer 152 may be interposed between conductive material 154 and substrate 105 (or spacer insulation layer 145). Barrier layer 152 may be formed from one or more materials, such as Ti, TiN, TiW, Ta, TaN, Cr, NiV, etc. Such materials and other relatively “hard” materials are routinely used to form diffusion barriers in semiconductor devices. These materials prevent the diffusion or migration of atoms from near-by layers and/or regions (e.g., conductive pad 120) into electrode 155. Such migration has been shown to adversely affect the long-term performance and reliability of electrode 155.

In certain embodiments of the invention, barrier layer 152 may be implemented as a composite layer. That is, multiple barrier layers may be used to form diffusion barrier 152 around all or some portion of electrode 155. Consider, for example, the embodiment shown in FIG. 10. Here, a second barrier layer 153 is formed on first barrier layer 152 and on the inner surfaces of second via hole 150. Thus, the entirety of electrode 155 is compassed around by at least one layer of a composite barrier. Second barrier layer 153 may be formed from one or more of the same materials used to form first barrier layer 152.

In the foregoing embodiments, it should be noted that while compositional layer 115 may be variously implemented, a primary purpose of compositional layer 115 remains the effective insulation of under-laying certain components and/or layers. For example, conductive pad 120 is insulated from semiconductor substrate 105 by compositional layer 115 (or the combination of compositional layer 115 and spacer insulation layer 145). Thus, while compositional layer 115 may be formed by multiple conductive and insulating layers (or may selectively incorporate one or more conductive layers or functional elements), those portions of compositional layer 115 separating conductive pad 120 from semiconductor substrate 105 and penetrated by electrode 155 will be insulating in their electrical nature, and will generally not consist of conductive layers that are not intended to be connected to electrode 155.

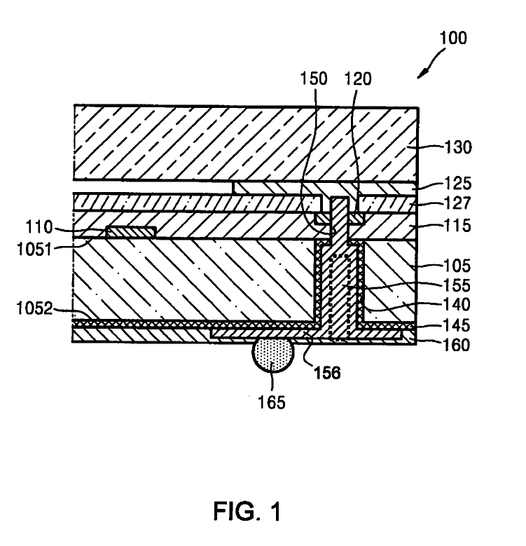

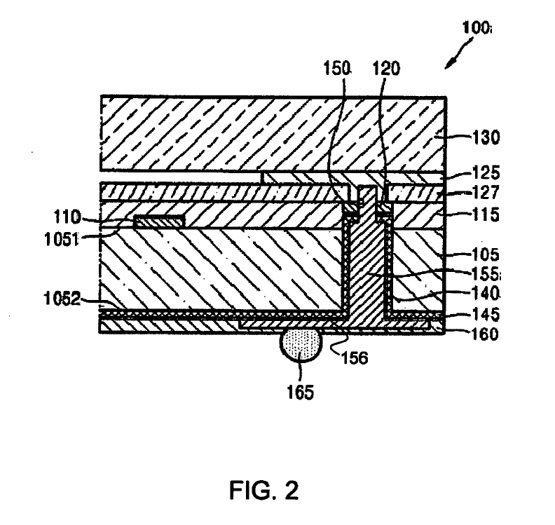

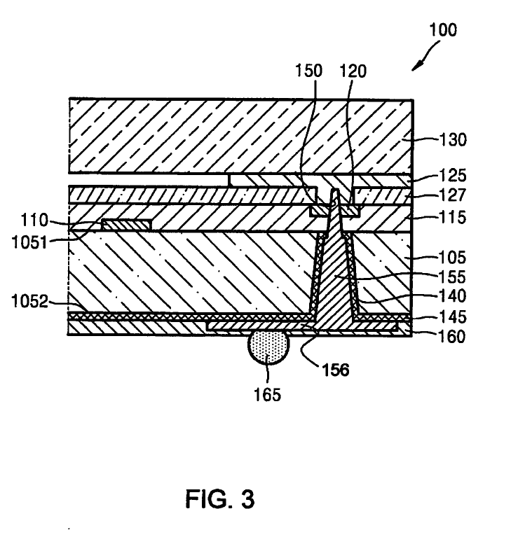

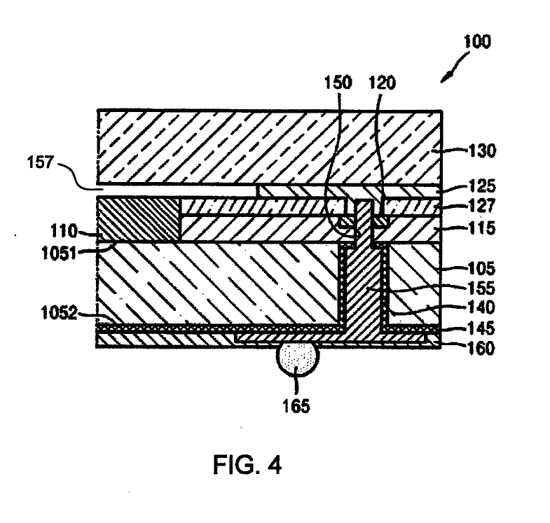

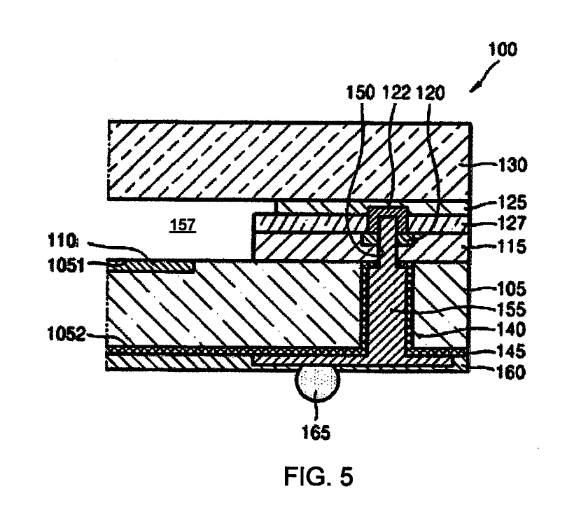

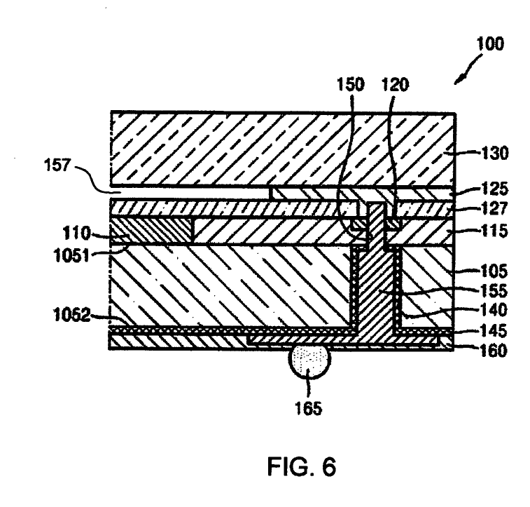

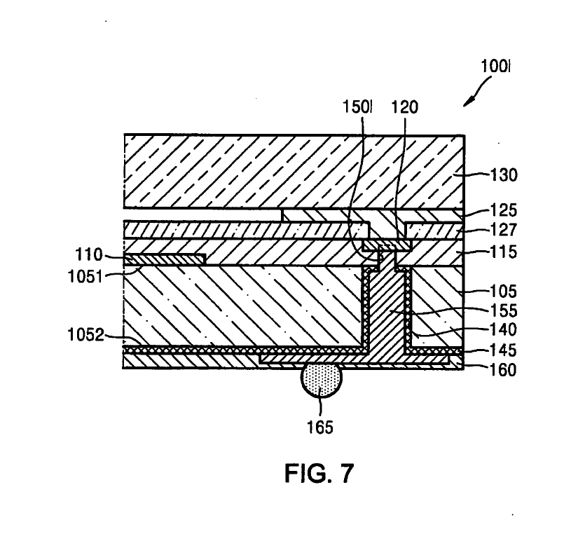

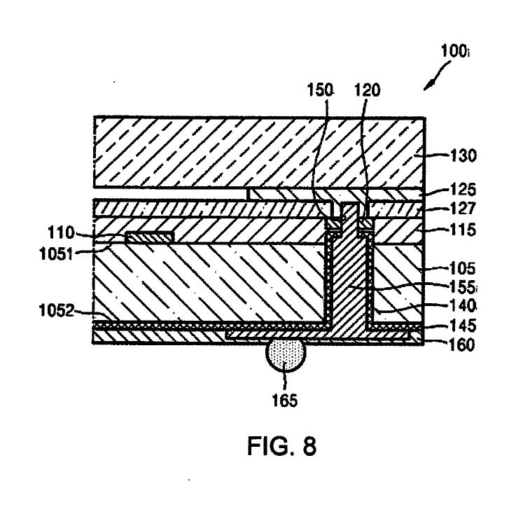

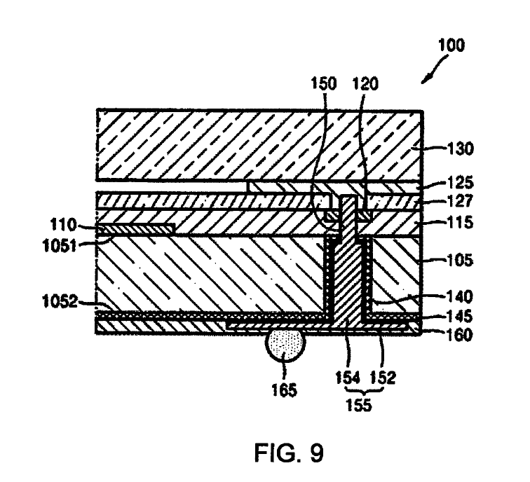

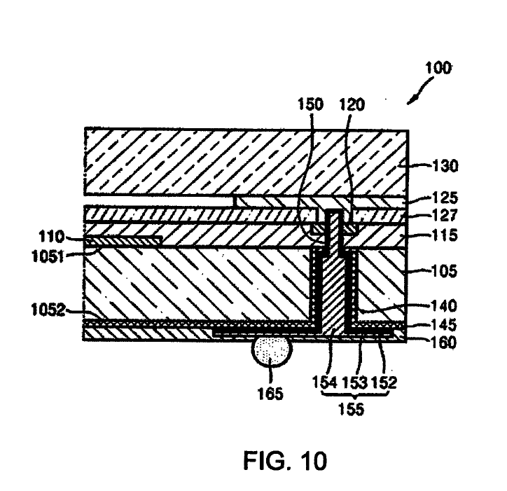

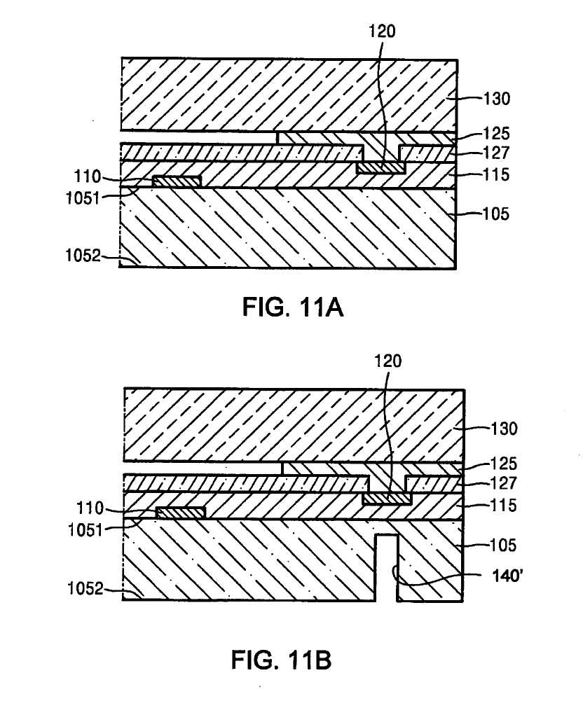

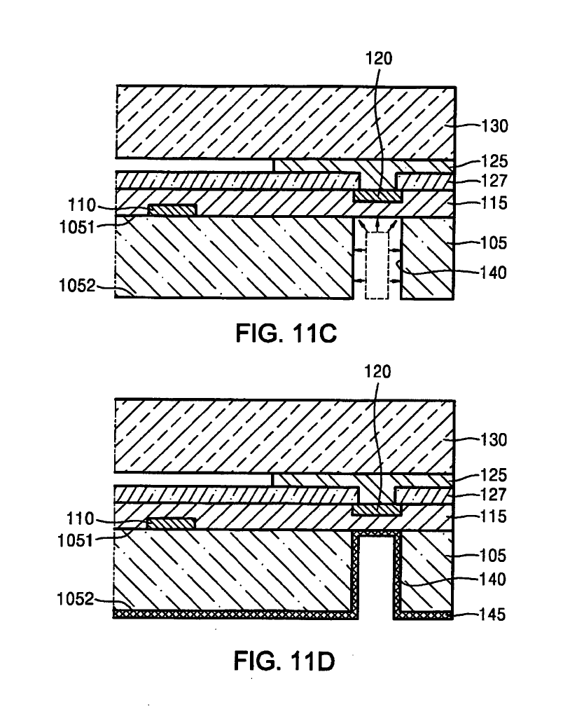

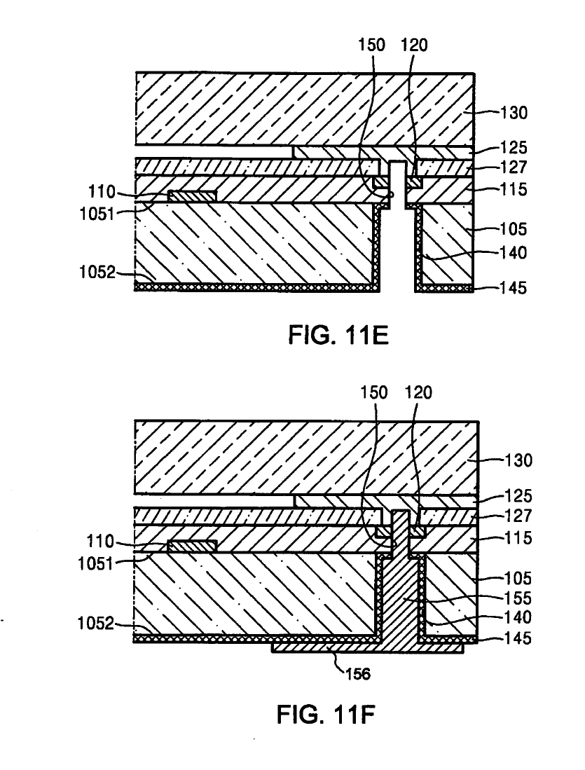

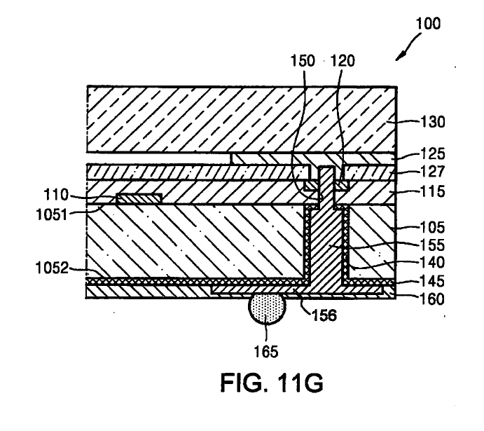

FIGS. 11A through 11G (collectively FIG. 11) are related schematic diagrams illustrating an exemplary method of forming a semiconductor device in accordance with an embodiment of the invention. More particularly, FIGS. 11A through 11G illustrate a method of forming a semiconductor package 100 such as the one illustrated in FIG. 1.

Referring to FIG. 11A, semiconductor device 110 is disposed on semiconductor substrate 105. Next, compositional layer 115 is formed on semiconductor substrate 105 to cover semiconductor device 110. Then, conductive pad 120 is formed on compositional layer 115. Typically, an electrical wiring or plug is formed to connect conductive pad 120 with semiconductor device 110.

Next, passivation layer 127 is formed on compositional layer 115 and an opening is formed through passivation layer 127 to expose a portion of conductive pad 120. It should again be noted that passivation layer 127 is optional, and semiconductor package 100 may be formed without passivation layer 127. Nevertheless, those skilled in the art will recognize various benefits of including passivation 127 in selected embodiments of the invention.

Next, handling substrate 130 is arranged over semiconductor substrate 105. Adhesive layer 125 is selectively formed on passivation layer 127, compositional layer 115, and/or the exposed portion of conductive pad 120. Then, handling substrate 130 is bonded by adhesive 125 to passivation layer 127 and/or compositional layer 115. It should be noted that adhesive 125 and handling substrate 130 are optional features and may be omitted from the embodiment of FIG. 11. Alternatively, handling substrate 130 may be replaced by one or more protective layers. Nevertheless, those skilled in the art will recognize certain benefits of including handling substrate 130 in selected embodiments of the invention. For example, handling substrate 130 may provide a desired amount of protection and structural stability to semiconductor package 100 during the packaging process.

Before or after handling substrate 130 is bonded to passivation layer 127 and/or compositional layer 115, the bottom surface of semiconductor substrate 105 may be polished or etched to reduce its thickness. For example, in one embodiment of the invention, lower surface 1052 of semiconductor substrate 105 is chemically-mechanically polished to a thickness of about 50 μm.

Referring to FIG. 11B, a groove 140′ is formed in semiconductor substrate 105. As seen in FIG. 11B, groove 140′ extends upward from lower surface 1052 of semiconductor substrate 105.

Groove 140′ may be formed using a laser drilling process or dry etching process. Where dry etching is used to form groove 140′, an etching mask is generally formed on lower surface 1052 of semiconductor substrate 105 to define the geometry (e.g., the position, lateral width, etc.) of groove 140′. On the other hand, laser etching does not typically require the use of an etching mask. In the illustrated embodiment, the laser drilling or dry etching is controlled in such a manner that the depth of groove 140′ does not expose compositional layer 115.

Referring to FIG. 11C, first via hole 140 is formed by expanding groove 140′. First via hole 140 may be formed to extend completely through semiconductor substrate 105 and expose compositional layer 115.

In one embodiment, groove 140′ is expanded using an isotropic etching process. The selectivity of the isotropic etching process is controlled such that semiconductor substrate 105 is etched but compositional layer 115 is not substantially etched. The isotropic etching process typically comprises a wet etching process or a chemical dry etching process.

Referring to FIG. 11D, spacer insulation layer 145 is formed to cover the exposed inner surfaces of first via hole 140 and bottom surface 1052 of semiconductor substrate 105. Spacer insulation layer 145 may be formed using chemical vapor deposition (CVD), physical vapor deposition (PVD), or polymer spraying.

Referring to FIG. 11E, second via hole 150 is formed through spacer insulation layer 145, compositional layer 115, and at least a portion of conductive pad 120. In the illustrated embodiment, second via hole 150 is formed completely through conductive pad 120, but in other embodiments second via hole 150 extends through only a portion of conductive pad 120.

Second via hole 150 is typically formed with a smaller cross-section than first via hole 140. However, second via hole 150 may be formed with the same cross-sectional width as first via hole 140. Moreover, although first and second via holes 140 and 150 shown in FIG. 11E are respectively formed with substantially fixed cross-sectional widths, first and second via holes 140 and 150 may alternatively be formed with tapered shapes such as those illustrated in FIG. 3.

Second via hole 150 may be formed using laser drilling. However, in an alternate embodiment, second via hole 150 may be formed using a dry etching process. In order to perform the dry etching process, an etching mask is formed on the bottom surface of semiconductor substrate 105 and first via hole 140 to define the cross-sectional width of second via hole 150. The dry etching process is then performed using the etching mask to protect semiconductor substrate 105 and spacer insulation layer 145.

Referring to FIG. 11F, electrode 155 is formed by filling first and second via holes 140 and 150 with (optionally) one or more barrier layer(s) followed by one or more conductive layers. In one embodiment of the invention, electrode 155 may be formed using an Al PVD deposition method. Alternately, electrode 155 may be formed by first plating the exposed inner surfaces of first via hole 140 and second via hole 150 with a seed layer of Cu, and thereafter filling (or partially filing) first via hole 140 and second via hole 150 with one or more conductive materials. The conductive material used to form electrode 155 may comprise a metal (or metal alloy) such as aluminum (Al) or copper (Cu).

Electrode 155 may completely fill the first and second via holes 140 and 150, as shown in FIG. 11F, or electrode 155 may partially fill first and second via holes 140 and 150, as suggested by the dotted line portion indicated in FIG. 1. As previously noted with respect to the embodiments shown in FIGS. 9 and 10, a barrier layer may also be formed in relation to electrode 155. The barrier layer(s) and/or conductive layer(s) may be additionally patterned to form re-routing layer 156 on lower surface 1052 of semiconductor substrate 105 which may serve as a lateral re-distribution portion of electrode 155, as desired.

As before, electrode 155 may be insulated from semiconductor substrate 105 by spacer insulation layer 145. In addition, electrode 155 is electrically connected to conductive pad 120 through second via hole 150.

Referring to FIG. 11G, insulation layer 160 is formed to cover electrode 155 and spacer insulation layer 145 on the lower surface 1052 of semiconductor substrate 105. Insulation layer 160 may be formed using CVD process or spin coating.

After insulation layer 160 is formed, an opening may be formed to selectively expose a portion of re-routing layer 156 or a portion of electrode 155. Terminal 165 may then be connected to re-routing layer 156 through the opening in insulation layer 160. In the illustrated embodiment, terminal 165 is implemented as a solder ball or solder bump, but other conventionally understood elements might be used in the alternative.

As an alternative to the embodiment illustrated in FIG. 11G, the opening in insulation layer 160 may be formed directly under and vertically aligned with first and second via holes 140 and 150. In this manner, terminal 165 may be connected directly under electrode 155 through an opening. In such an alternate embodiment, electrode 155 may be formed without re-routing portion 156. In yet another embodiment, multiple external terminals may be connected to electrode 155 through multiple openings in insulation layer 160 along the lower surface 1052 of semiconductor substrate 105.

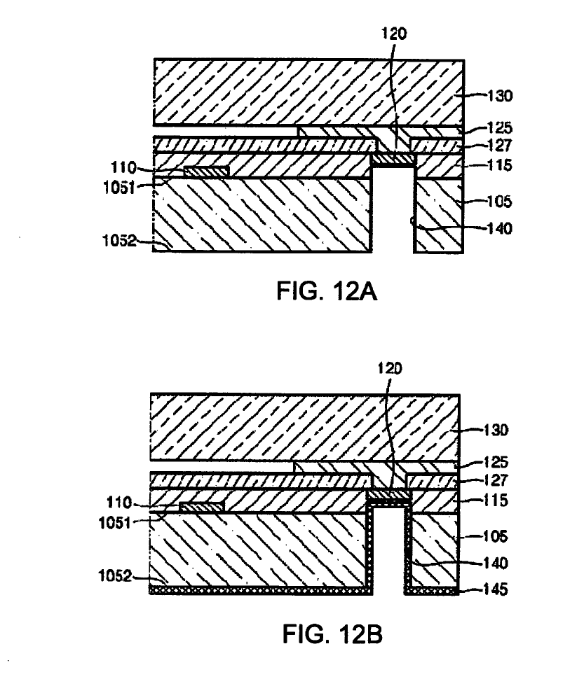

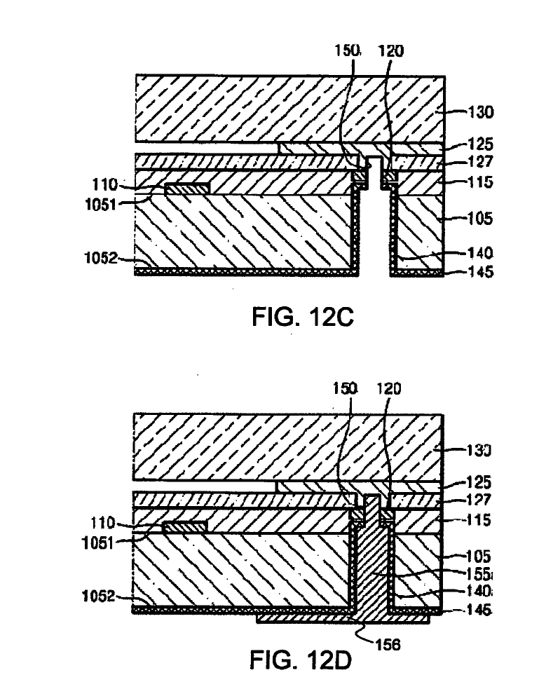

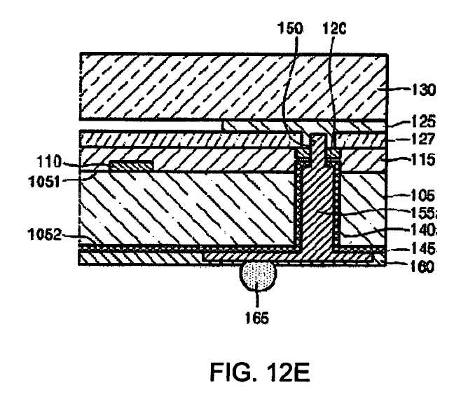

FIGS. 12A through 12E (collectively FIG. 12) are related schematic diagrams illustrating another exemplary method of forming a semiconductor device in accordance with an embodiment of the invention. In many aspects, the method of FIG. 12 is similar to the method of FIG. 11. Accordingly, some details provided above will be omitted from the description of FIG. 12.

Referring to FIG. 12A, first via hole 140 is formed through semiconductor substrate 105 and a portion of compositional layer 115. The depth of first via hole 140 is controlled to prevent exposure of the lower surface of conductive pad 120. Again, first via hole 140 may be formed using a dry etching process and/or a wet etching process. Depending on the process used to form first via hole 140, it may be necessary to form an etching mask on the bottom surface of semiconductor substrate 105 before forming first via hole 140.

Referring to FIG. 12B, spacer insulation layer 145 is next formed on the lower surface 1052 of semiconductor substrate 105 and on exposed inner surfaces of first via hole 140.

Referring to FIG. 12C, second via hole 150 is formed through spacer insulation layer 145, the residual portion of compositional layer 115, and at least a portion of conductive pad 120.

Second via hole 150 typically has a smaller cross-sectional width than first via hole 140. However, second via hole 150 may be formed with the same cross-sectional width as first via hole 140. Moreover, although first and second via holes 140 and 150 shown in FIG. 12C are respectively formed with substantially fixed cross-sectional widths, first and second via holes 140 and 150 may alternatively be formed with tapered shapes such as those illustrated in FIG. 3.

Referring to FIG. 12D, electrode 155 is formed by filling first and second via holes 140 and 150 with one or more barrier layer(s) and/or one or more conductive layer(s). Electrode 155 may completely fill first and second via holes 140 and 150, as shown in FIG. 11F, or electrode 155 may only partially fill first and second via holes 140 and 150. A barrier layer comprising titanium (Ti), titanium nitride (TiN), tantalum (Ta), or tantalum nitride (TaN) may be used in relation to electrode 155. The conductive layer may comprise a metal such as aluminum (Al) or copper (Cu). In the illustrated embodiment, the barrier layer and/or conductive layer are patterned to cover a portion of lower surface 1052 of semiconductor substrate 105 to form re-routing layer 156 of electrode 155.

Electrode 155 is insulated from semiconductor substrate 105 by spacer insulation layer 145. In addition, electrode 155 is electrically connected to conductive pad 120 through second via hole 150.

Referring to FIG. 12E, insulation layer 160 is formed to cover portions of electrode 155 and spacer insulation layer 145 formed on lower surface 1052 of semiconductor substrate 105. Insulation layer 160 may be formed using a CVD process or spin coating.

An opening is then formed in insulation layer 160 to expose a portion of re-routing layer 156 of electrode 155. Terminal 165 is then connected to re-routing layer 156 of electrode 155 through the opening in insulation layer 160.

As an alternative to the embodiment illustrated in FIG. 12E, the opening in insulation layer 160 may be formed directly under and in vertical alignment with first and second via holes 140 and 150, such that terminal 165 is disposed directly under electrode 155. In such an embodiment, electrode 155 will be formed without re-routing layer 156. In yet another alternative embodiment, multiple external terminals may be connected to electrode 155 through multiple openings formed in insulation layer 160 along lower surface 1052 of semiconductor substrate 105.

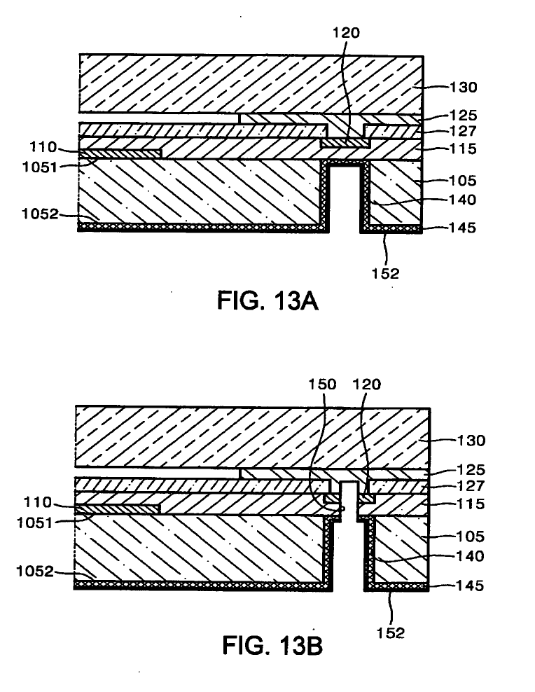

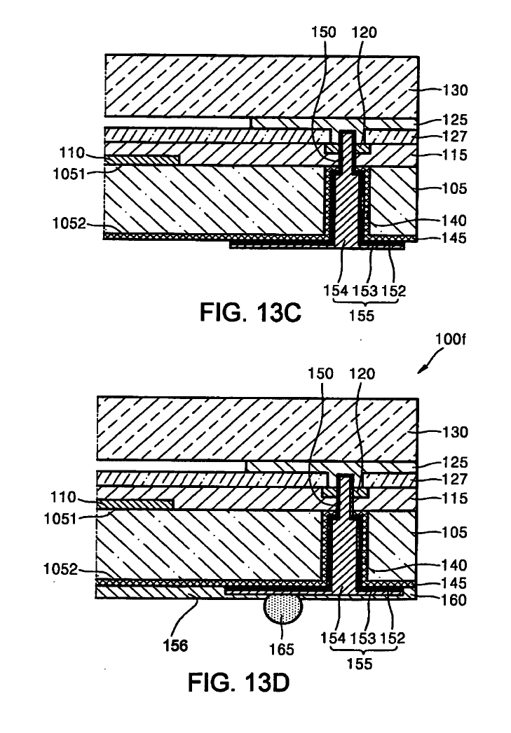

FIGS. 13A through 13D (collectively FIG. 13) are related schematic diagrams illustrating another exemplary method of forming a semiconductor device in accordance with an embodiment of the invention. In many aspects, the method of FIG. 13 is similar to the methods of FIGS. 11 and 12. Accordingly, some details provided above will be omitted from the description of FIG. 13.

In FIG. 13A, first via hole 140 is formed through the thickness of substrate 105 but does not extend into compositional layer 115. Spacer insulation layer 145 and a first barrier layer 152 are sequentially formed on exposed inner surfaces of first via hole 140 and on lower surface 1052 of substrate 105.

Thereafter, as shown in FIG. 13B, second via hole 150 is formed through compositional layer 115 and conductive pad 120. Since second via hole 150 penetrates conductive pad 120 debris or residue from the via formation might contaminate the surface of spacer insulation layer 145, but for the presence of barrier layer 152.

As shown in FIG. 13C, following the formation of second via 150, second barrier layer 153 is formed on exposed inner surfaces of second via 150 and on first barrier layer 152 in first via hole 140. Second barrier layer 153 may be used to form a smooth and uniform under-layer to the subsequent formation of conductive material 154 filling (or partially filling) residual portions of first via hole 140 and second via hole 150.

As shown in FIG. 13D, insulation layer 160 is then formed as before to cover re-routing portion 156 of electrode 155, including first barrier layer 152 and second barrier layer 153, on lower surface 1052 of substrate 105.

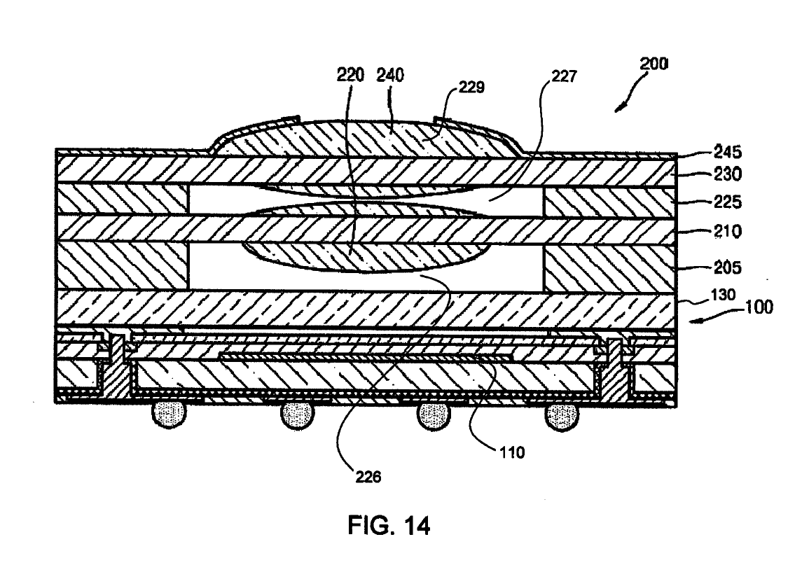

FIG. 14 is a schematic diagram illustrating an optical device module 200 incorporating one or more aspects of a semiconductor package consistent with an embodiment of the invention.

Referring to FIG. 14, optical device module 200 may comprise semiconductor package 100, as illustrated in FIG. 1. Alternatively, package module 200 may comprise a semiconductor package having any one of the forms described in relation to FIGS. 2 through 10.

In optical device module 200, semiconductor device 100 is assumed to comprise an active pixel sensor or an active pixel sensor array for an imaging device such as a camera. For example, the active pixel sensor may be a complementary metal oxide semiconductor (CMOS) sensor or a charge-coupled device (CCD) sensor.

First support members (or spacers) 205 are formed on handling substrate 130 of semiconductor package 100 and a first transparent substrate 210 is formed on first support members 205. A first lens component 226 is formed between first support members 205 under first transparent substrate 210 and disposed in vertical alignment with semiconductor device 110.

Second support members 225 are then formed on first transparent substrate 210 and a second transparent substrate 230 is formed on second support members 225. A second lens component 227 is formed between second support members 225 on second transparent substrate 230 and disposed in vertical alignment with first lens component 226 and semiconductor device 110.

An aperture 245 is formed on second transparent substrate 230. Aperture 245 is disposed around a third lens component 229. Aperture 245 is used to control the transmission of light to semiconductor device 110. Aperture 245 may be formed from a photoresist layer, for example.

Lighting transmitted through aperture 245 to semiconductor device 110 passed through spherical first and second lenses 220 and 240. First lens 220 is implemented in the illustrated embodiment by the combination of first lens component 226, first transparent substrate 210 and a lower portion of second lens component 227. Second lens 240 is implemented in the illustrated embodiment by the combination of third lens component 229, second transparent substrate 230 and an upper portion of second lens component 227. Thus, optical device module 200 of FIG. 14 assumes the use of spherical first and second lenses 220 and 240. However, non-spherical lenses may be used alternately and/or additionally within package module 200. In addition, although two lenses are shown in FIG. 14, package module 200 may be modified to use more or fewer lenses.

Further, the optical device module illustrated in FIG. 14 may be further modified to incorporate one or more optical filters of conventional design. For example, an infrared (IR) filter may be associated with any one of the transparent substrates described above. Similarly, a color filter may be incorporated into the optical device module.

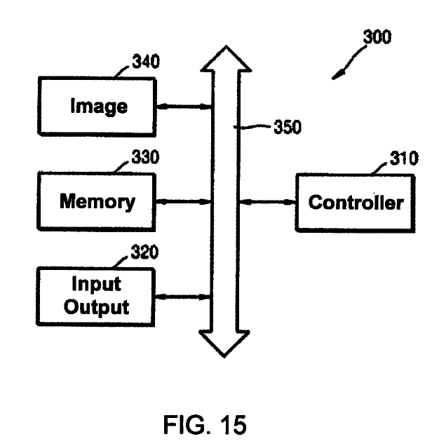

FIG. 15 is a general block diagram of an exemplary system 300 incorporating a semiconductor package such as semiconductor package 100 illustrated, for example, in FIGS. 1 through 10. In system 300, semiconductor package 100 may be incorporated within an image sensor 340 and/or a memory 330.

Referring to FIG. 15, system 300 comprises image sensor 340, memory 330, an input/output device 320, and a controller 310, all operatively connected via a bus 350. Image sensor 340, memory 330, input/output device or interface 320, and controller 210 communicate data, address information, control signals, etc., via bus 350.

Controller 310 typically comprises a processor adapted to execute commands controlling system 300. Controller 310 may be implemented using, for example, a microprocessor, a digital signal processor, a microcontroller, etc. Input/output device 320 may be implemented using one or more conventional devices, such as a keyboard, a display device, etc. Memory 330 may be implemented with a memory array adapted to store data provided by input/output device 320, image sensor 240, and/or controller 310. Image sensor 340 may be implemented with an active pixel sensor array, including one or more lens focusing light onto the active pixel sensor array.

As described above, semiconductor package 100 may be located within image sensor 340 or memory 330. Where semiconductor package 100 is located within image sensor 340, semiconductor package 100 may be attached to a package module such as that illustrated in FIG. 14. In such a case, semiconductor device 110 comprises an active pixel sensor or an active pixel sensor array. On the other hand, where semiconductor package 100 is located within memory 330, semiconductor device 110 may comprise one or more memory elements such as a memory cell array.

By incorporating a semiconductor package designed and implemented in accordance with an embodiment of the invention with image sensor 340 and/or memory 330, superior electrical connections may be provided between a constituent semiconductor device 110 and associated components of system 300. As a result, the reliability of system 300 will be improved.

Whether embodied in a system or a semiconductor package, the present invention in its numerous different forms provides an improved electrical performance in relation to an electrode and a semiconductor substrate penetrated by the electrode. This improved electrical performance facilitates the formation of more reliable electrode connections to conductive pads. This improved performance may be provided even where the electrode is formed in partial or complete penetration of the conductive pad.

The foregoing exemplary embodiments are teaching examples. Those of ordinary skill in the art will understand that various changes in form and details may be made to the exemplary embodiments without departing from the scope of the invention as defined by the following claims.

1. A semiconductor integrated circuit (IC) package, comprising:
a substrate having a first surface and a second surface;
a compositional layer formed on the first surface;
a conductive pad formed on, or formed at least partially in the compositional layer;
an electrode comprising a first part extending through the substrate from the second surface, and a second part extending from the first part through the compositional layer to electrically contact the conductive pad; and
a spacer insulation layer separating the first part of the electrode from the substrate.

2. The package of claim 1, wherein the spacer insulation layer separates only the first part of the electrode from the substrate, and the second part of the electrode contacts the compositional layer.

3. The package of claim 1, wherein the electrode further comprises a re-routing layer formed on the second surface of the substrate, and the package further comprises:
an insulation layer disposed on the second surface of the substrate and covering re-routing layer; and
a terminal connected to the electrode through an opening in the insulation layer.

4. The package of claim 1, further comprising:
a semiconductor device disposed on, or at least partially in the substrate; and
a passivation layer formed on the composition layer and covering the semiconductor device, wherein an opening in the passivation layer exposes at least a portion of the conductive pad.

5. The package of claim 4, further comprising:
a handling substrate adhered to at least a portion of the passivation layer with an adhesive.

6. The device of claim 5, wherein the handling substrate is formed from a transparent material.

7. The package of claim 1, wherein the conductive pad is embedded within the compositional layer.

8. The package of claim 1, wherein the first part of the electrode extends at least partially into the compositional layer.

9. The package of claim 1, wherein the spacer insulation layer and the first part of the electrode are disposed in a first via hole extending completely through the substrate; and
wherein the spacer insulation layer is conformally formed on inner surfaces of the first via hole and the first part of the electrode is conformably formed on the spacer insulation layer, such that the first via hole is not completely filled.

10. The package of claim 1, wherein at least one of the first and second parts of the electrode has a tapered cross-section that decreases as its extends from the second surface of the substrate.

11. The package of claim 1, wherein the semiconductor device is electrically connected to the electrode.

12. The package of claim 11, wherein the semiconductor device comprises an active pixel sensor.

13. The package of claim 1, wherein the second part of the electrode extends completely through the conductive pad.

14. The package of claim 13, further comprising:
a passivation layer formed on the compositional layer, wherein an opening in the passivation layer exposes at least a portion of the conductive pad and a portion of the second part of the electrode extending through the conductive pad; and
a bump structure formed on the portion of the second part of the electrode extending through the conductive pad.

15. The package of claim 1, further comprising:
a semiconductor device formed on, or at least partially in the substrate and not covered by the compositional layer;
a passivation layer formed on the compositional layer, wherein an opening in the passivation layer exposes at least a portion of the conductive pad, and wherein the combined thickness of the compositional layer and the passivation layer is substantially equal to the thickness of the semiconductor device; and
a handling substrate adhered to at least a portion of the passivation layer, such that a sealed internal space is formed between the semiconductor device and the handling substrate.

16. The package of claim 15, wherein the semiconductor device is an active pixel sensor or an optical filter.

17. The package of claim 1, wherein the second part of the electrode penetrates at least a portion of the conductive pad and the package further comprises a barrier layer formed between the first part of the electrode and the spacer insulation layer.

18. The package of claim 1, wherein the second part of the electrode penetrates at least a portion of the conductive pad and the package further comprises:
a first barrier layer formed between the first part of the electrode and the spacer insulation layer; and
a second barrier layer formed on the first barrier layer and between the second part of the electrode and the compositional layer.

19-29. (canceled)

30. A semiconductor integrated circuit (IC) optical device module, comprising:
a substrate having opposing first and second surfaces;
an active pixel sensor formed on the first surface;
a compositional layer formed on the first surface and contacting at least a portion of the active pixel sensor;
a conductive pad formed on, or formed at least partially in the compositional layer;
an electrode comprising a first part extending through the substrate from the second surface, and a second part extending from the first part through the compositional layer to reach the conductive pad;
a spacer insulation layer disposed between the first part of the electrode and the substrate; and
a transparent substrate disposed on the substrate over the active pixel sensor.

31. The module of claim 30, further comprising at least one lens arranged in relation to the active pixel sensor.

32. The module of claim 31, wherein the at least one lens comprises a lens component formed in relation to the transparent substrate.

33. The module of claim 30, further comprising:
an infrared (IR) filter arranged in relation to the active pixel sensor and associated with the transparent substrate.

34. The module of claim 30, wherein the active pixel sensor is a complementary metal oxide semiconductor (CMOS) sensor or a charge-coupled device (CCD) sensor.

35. The module of claim 30, wherein at least one of the first and second parts of the electrode has a tapered cross-sectional width that decreases from the second surface.

36. The module of claim 30, wherein the first part of the electrode is formed in a first via hole extending completely through the substrate from the second surface; and
wherein the spacer insulation layer is conformably formed on inner surfaces of the first via hole and the first part of the electrode is conformally formed on the spacer insulation layer, such that the first via hole is not completely filled.

37. The module of claim 30, further comprising:
an insulation layer formed on the second surface of the substrate; and
a terminal connected to the electrode through an opening in the insulation layer.

38. The module of claim 30, wherein the second part of the electrode extends at least partially through the conductive pad.

39. The module of claim 38, further comprising a barrier layer formed between the first part of the electrode and the spacer insulation layer.

40. An electronic system, comprising:
a controller operatively connected to a semiconductor package via a bus;
an input/output (IO) interface allowing data transfers between the semiconductor package and the controller via the bus;
wherein the semiconductor package comprises:
a substrate having opposing first and second surfaces;
a semiconductor device disposed on the first surface of the substrate;
a compositional layer formed on the first surface of the substrate and contacting at least a portion of the semiconductor device;
a conductive pad formed on, or formed at least partially in the compositional layer;
an electrode comprising a first part extending through the substrate from the second surface, and a second part extending from the first part through the compositional layer to reach the conductive pad; and
a spacer insulation layer separating the first part of the electrode from the substrate.

41. The system of claim 40, wherein the semiconductor device comprises an image sensor.

42. The system of claim 41, wherein the image sensor comprises a complementary metal oxide semiconductor (CMOS) image sensor or a charge-coupled device (CCD) image sensor.

43. The system of claim 40, wherein the semiconductor device comprises a memory chip.

44. The system of claim 40, wherein the second part of the electrode extends at least partially through the conductive pad.

45. The system of claim 44, further comprising a barrier layer formed between the first part of the electrode and the spacer insulation layer.

46. The system of claim 40, further comprising:
an insulation layer formed on the second surface of the substrate; and
a terminal connected to the electrode through an opening in the insulation layer.

47. The system of claim 40, wherein the first part of the electrode extends through at least a portion of the compositional layer.

48. The system of claim 40, wherein at least one of the first and second parts of the electrode has a tapered cross-sectional width that decreases from the second surface.
